(19) United States
(12) Patent Application Publication
(10) Pub. No.: US 2019/0057882 A1
(43) Pub. Date: Feb. 21, 2019

(54) TWO-FLUID NOZZLE AND SUBSTRATE PROCESSING APPARATUS AND METHOD USING THE SAME

(71) Applicant: Samsung Electronics Co., Ltd., Suwon-si (KR)

(72) Inventors: Tae-Hong KIM, Seoul (KR); Jung-Min OH, Incheon (KR); Jin-Kyu KIM, Suwon-si (KR); So-Young PARK, Hapcheon-gun (KR); Kang-Suk LEE, Cheonan-si (KR)

(73) Assignee: SEMES CO., LTD., Cheonan-si (KR)

(21) Appl. No.: 15/867,791

(22) Filed: Jan. 11, 2018

(30) Foreign Application Priority Data
Aug. 18, 2017 (KR) 10-2017-0104764

(51) Int. Cl. H01L 21/67; B05B 7/24; B05B 7/04; B05B 12/08; B05B 13/02; B08B 3/02; B08B 3/10

(52) U.S. Cl. CPC H01L 21/67051; B05B 7/24; B05B 7/0483; B08B 3/10; B05B 12/085; B05B 13/0228; B08B 3/02; B05B 7/0433

(57) ABSTRACT

A nozzle includes a nozzle body having a hollow portion, and a mixing chamber and a discharge guide sequentially connected to the hollow portion, and an engagement member having a gas supply passage formed to supply a gas therethrough, inserted and fixed into the hollow portion and spaced apart from an inner face of the hollow portion to form a liquid gas supply passage which supplies a liquid toward a central axis of an exit of the gas supply passage. The mixing chamber is connected to the gas supply passage and the liquid supply passage to form liquid droplets. The gas supply passage has a first cross-sectional area, the mixing chamber has a second cross-sectional area substantially the same as the first cross-sectional area, and the discharge guide has a third cross-sectional area smaller than the first cross-sectional area.

### PRIORITY STATEMENT

This application claims priority under 35 U.S.C. § 119 to Korean Patent Application No. 10-2017-0104764 filed on Aug. 18, 2017 in the Korean Intellectual Property Office (KIPO), the contents of which are herein incorporated by reference in their entirety.

### BACKGROUND

### 1. Field

Example embodiments relate to a nozzle and a substrate processing apparatus and method using the same. More particularly, example embodiments relate to an internal mixing type two-fluid nozzle and a substrate processing apparatus and method using the same.

### 2. Description of the Related Art

Contaminants such as particles, organic contaminants, and metallic contaminants on a surface of a substrate greatly influence the characteristics and yield rate of semiconductor devices. Thus, in manufacturing of semiconductor devices, a cleaning process may be performed to remove contaminants attached to a substrate. In the cleaning process, an internal mixing type two-fluid nozzle where liquid droplets (mist) is formed by mixing gas and liquid inside the nozzle may be used.

However, in a conventional two-fluid nozzle, because a discharge passage through which a gas is injected is often complex, large amount of energy may be dissipated when the gas and a liquid are mixed to form the liquid droplets or may be lost due to friction generated on a passage in which the mixed gas and liquid are accelerated, to unbalance the distribution of the liquid, thereby deteriorating cleaning efficiency.

### SUMMARY

Example embodiments provide a two-fluid nozzle capable of forming liquid droplets having a high impact force and improving cleaning efficiency.

Example embodiments provide a substrate processing apparatus and method having the above-mentioned two-fluid nozzle.

According to example embodiments, a nozzle includes a gas supply passage extending in a first direction along an axis to supply a gas therethrough, a liquid supply passage surrounding the gas supply passage along a lengthwise direction of the gas supply passage to supply a liquid toward a central axis of an exit of the gas supply passage, a mixing chamber extending in the first direction, spaced apart from the exit of the gas supply passage and opening to the gas supply passage and the liquid supply passage to mix the gas and the liquid to form liquid droplets, and a discharge guide arranged coaxially with the axis of the gas supply passage and in fluid communication with the mixing chamber to inject the liquid droplets to the outside of the nozzle. The gas supply passage has a first cross-sectional area, the mixing chamber has a second cross-sectional area substantially the same as the first cross-sectional area, and the discharge guide has a third cross-sectional area smaller than the first cross-sectional area.

According to example embodiments, a nozzle includes a nozzle body having a hollow portion, and a mixing chamber and a discharge guide sequentially connected to the hollow portion, and an engagement member having a gas supply passage formed to supply a gas therethrough, inserted and fixed into the hollow portion and spaced apart from an inner face of the hollow portion to form a liquid supply passage which supplies a liquid toward a central axis of an exit of the gas supply passage. The mixing chamber is connected to the gas supply passage and the liquid supply passage to form liquid droplets. The gas supply passage has a first cross-sectional area, the mixing chamber has a second cross-sectional area substantially the same as the first cross-sectional area, and the discharge guide has a third cross-sectional area smaller than the first cross-sectional area.

According to example embodiments, a substrate processing apparatus includes a support unit configured to support a substrate, and an injection unit having a nozzle configured to mix a gas and a liquid to form liquid droplets therein and inject the liquid droplet onto the substrate. The nozzle includes a gas supply passage extending in a first direction to supply the gas therethrough, a liquid supply passage surrounding the gas supply passage along a lengthwise direction of the gas supply passage to supply the liquid toward a central axis of an exit of the gas supply passage, a mixing chamber extending in the first direction, spaced apart from the exit of the gas supply passage and opening to the gas supply passage and the liquid supply passage to mix the gas and the liquid to form the liquid droplets, and a discharge guide arranged coaxially with an axis of the gas supply passage and in fluid communication with the mixing chamber to inject the liquid droplets to the outside. The gas supply passage has a first cross-sectional area, the mixing chamber has a second cross-sectional area substantially the same as the first cross-sectional area, and the discharge guide has a third cross-sectional area smaller than the first cross-sectional area.

According to example embodiments, a two-fluid nozzle may include a gas supply passage, a liquid supply passage and a mixing chamber and a discharge guide arranged coaxially with the gas supply passage. The mixing chamber may open to an exit of the gas supply passage and an exit of the liquid supply passage to mix a gas and a liquid to form liquid droplets. A diameter D1 of the gas supply passage may be substantially the same as a diameter D2 of the mixing chamber, and a diameter D3 of the discharge guide may be smaller than the diameter D1 of the gas supply passage. A length L2 of the discharge guide may be greater than a length L2 of the mixing chamber.

Thus, liquid droplets having a relatively high impact force may be generated to remove contaminants on a substrate, to thereby improve cleaning efficiency. The nozzle may be used as a relatively high flow rate nozzle or a high impact force nozzle.

Further, distribution plates may be formed within the liquid supply passage to improve flow uniformity of the supplied liquid, and the nozzle may include a conductive synthetic resin and may be grounded to remove an electrostatic charge in the liquid droplet.

### BRIEF DESCRIPTION OF THE DRAWINGS

Example embodiments will be more clearly understood from the following detailed description taken in conjunction with the accompanying drawings. FIGS. 1 to 10C represent non-limiting example embodiments as described herein.

FIG. 1 is a cross-sectional view illustrating a substrate processing apparatus in accordance with example embodiments.

FIG. 2 is a cross-sectional view illustrating a two-fluid nozzle of the substrate processing apparatus in FIG. 1.

FIG. 3 is an enlarged view illustrating a portion of a mixture chamber of the two-fluid nozzle in FIG. 2.

FIG. 4 is a perspective view illustrating an engagement member of the two-fluid nozzle in FIG. 2.

FIG. 5 is a cross-sectional view taken along the line A-A′ in FIG. 2.

FIG. 6 is a cross-sectional view taken along the line B-B′ in FIG. 2.

FIG. 7 is a cross-sectional view taken along the line C-C′ in FIG. 2.

FIG. 8 is a view illustrating a gas supply unit and a liquid supply unit of the substrate processing apparatus in FIG. 1.

FIGS. 9A to 9C are graphs illustrating an impact force (liquid-driving power) of injected liquid droplets according to a diameter ratio of a discharge guide and a gas supply passage (mixing chamber).

FIGS. 10A to 10C are graphs illustrating an impact force (liquid-driving power) of injected liquid droplets according to a length ratio of a discharge guide and a mixing chamber.

FIG. 11 is a flow chart showing a method of processing a substrate according to exemplary embodiments of the present disclosure.

### DETAILED DESCRIPTION OF EXAMPLE EMBODIMENTS

Hereinafter, example embodiments will be explained in detail with reference to the accompanying drawings.

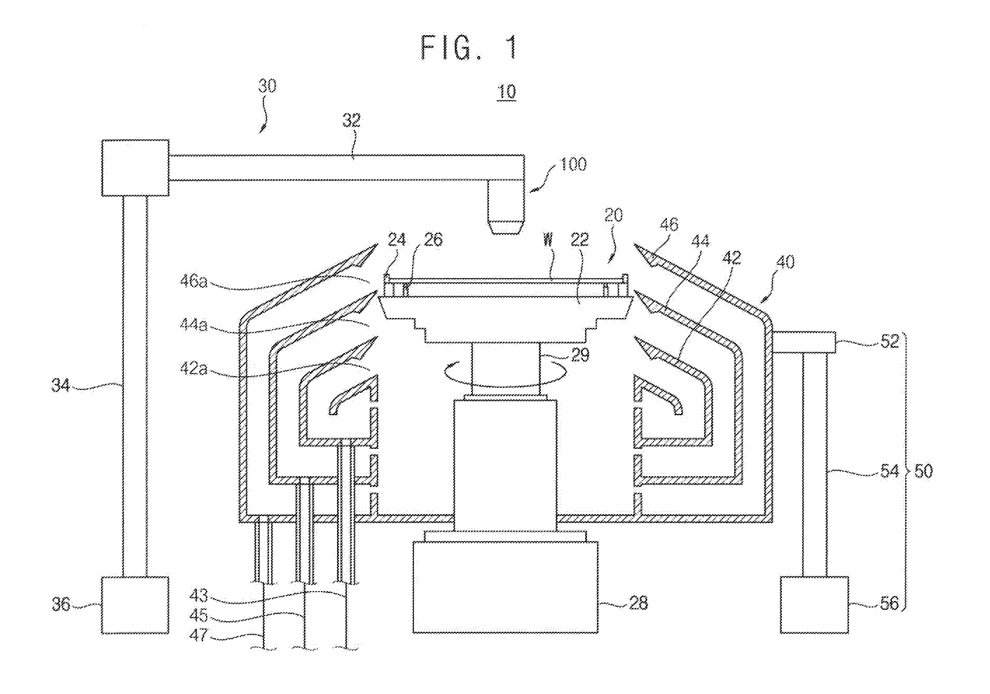

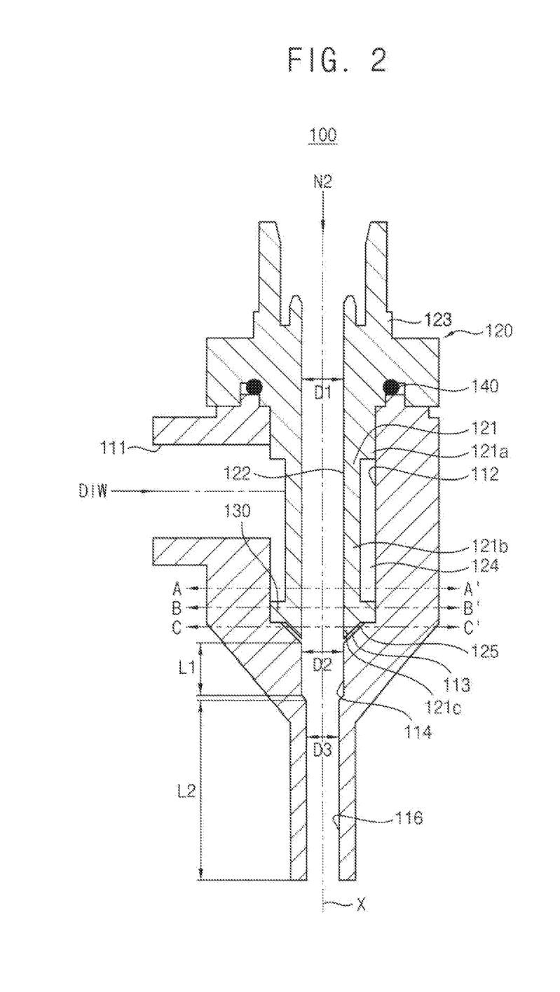

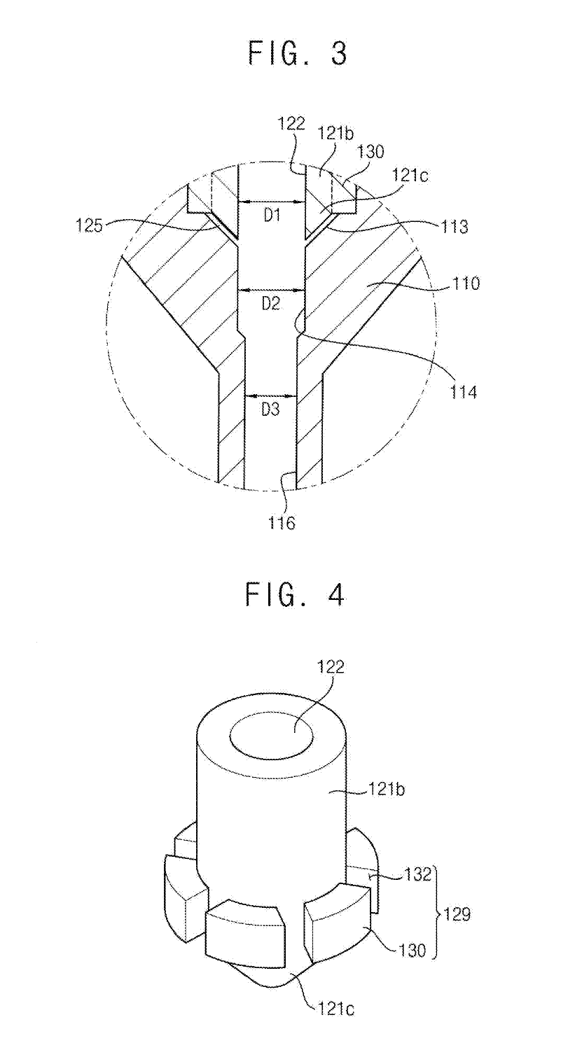

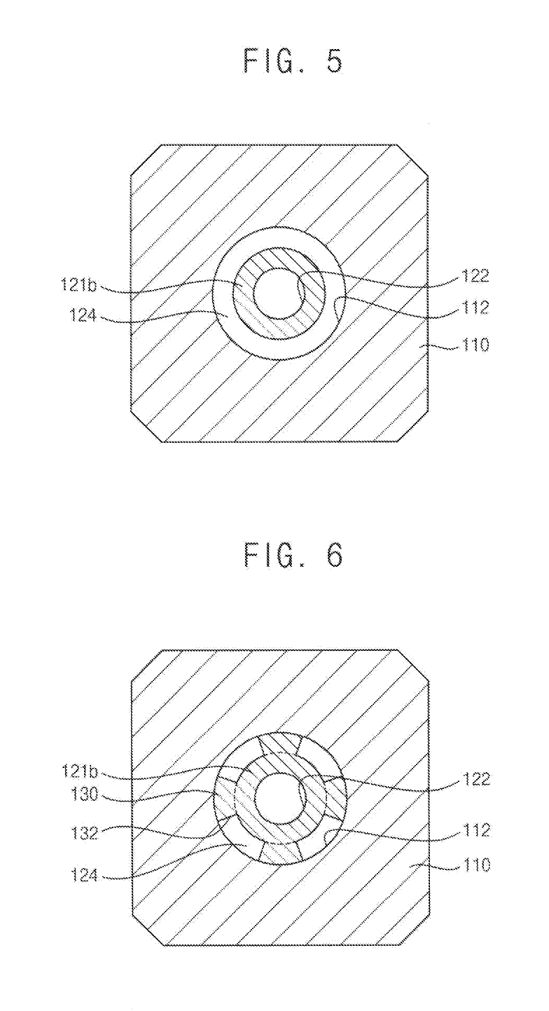

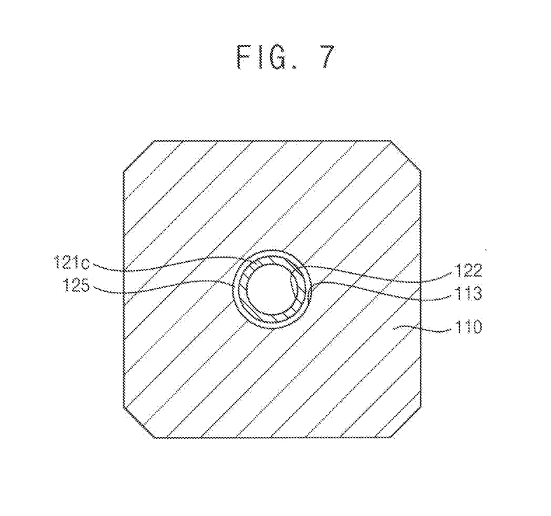

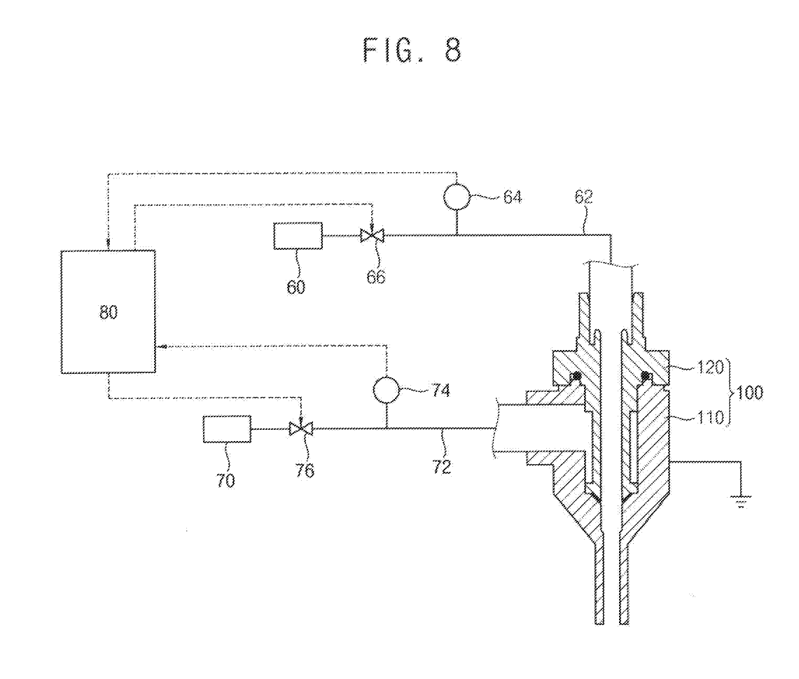

FIG. 1 is a cross-sectional view illustrating a substrate processing apparatus in accordance with example embodiments. FIG. 2 is a cross-sectional view illustrating a two-fluid nozzle of the substrate processing apparatus in FIG. 1. FIG. 3 is an enlarged view illustrating a portion of a mixture chamber of the two-fluid nozzle in FIG. 2. FIG. 4 is a perspective view illustrating an engagement member of the two-fluid nozzle in FIG. 2. FIG. 5 is a cross-sectional view taken along the line A-A′ in FIG. 2. FIG. 6 is a cross-sectional view taken along the line B-B′ in FIG. 2. FIG. 7 is a cross-sectional view taken along the line C-C′ in FIG. 2. FIG. 8 is a view illustrating a gas supply unit and a liquid supply unit of the substrate processing apparatus in FIG. 1.

Referring to FIG. 1, a substrate processing apparatus 10 (which may also be referred to as a substrate treating apparatus) may include a support unit 20 configured to support a substrate such as a wafer W and an injection unit 30 having a nozzle 100 configured to inject liquid droplets onto the substrate W. The nozzle 100 may be a two-fluid nozzle. The substrate processing apparatus 10 may further include a cup 40 surrounding the support unit 20 and configured to provide a space for processing the substrate W and an elevation unit 50 configured to move the cup 40 upward and downwards.

In example embodiments, the substrate processing apparatus 10 may be installed within a process chamber for performing a cleaning process on the substrate W. A plurality of the process chambers may be provided in a substrate treatment system. The process chambers may be arranged along a transfer chamber of the substrate treatment system. The substrate W may be transferred to the process chamber through the transfer chamber.

The substrate processing apparatus 10 disposed within each of the process chambers may have different structures according to the types of cleaning processes to be performed. However, in some embodiments, the substrate processing apparatus 10 within each of the process chambers may have the same structure. Alternatively, the process chambers may be classified into a plurality of groups, the process chambers may have different structures for groups.

As illustrated in FIG. 1, the support unit 20 may be arranged in a processing space of the cup 40 and may support and rotate the substrate W during the cleaning process. The support unit 20 may include a spin head 22, a holding member 24, a support pin 26, a driving portion 28 and a drive shaft 29. The spin head 22 may have an upper surface having a substantially circular shape when viewed from the top. The spin head 22 may be fixedly coupled to the drive shaft 29 which is rotated by the driving portion 28. Thus, as the driving shaft 29 is rotated, the spin head 22 may be rotated.

The spin head 22 may include the holding member 24 and the support pin 26 for supporting the substrate W.

A plurality of the holding members 24 may be arranged along a peripheral region of the upper surface of the spin head 22 to be spaced apart from each other by a predetermined distance. The holding member 24 may protrude upwards from the spin head 22 to contact and support a side surface of the substrate W. A plurality of support pins 26 may be arranged to have a generally annular ring shape through a combination thereof. The plurality of the support pins 26 may protrude upwards from the spin head 22 to contact and support a bottom surface of the substrate W. The plurality of support pins 26 may support a periphery of the bottom surface of the substrate W such that the substrate W is spaced apart from the upper surface of the spin head 22 by a predetermined distance.

The injection unit 30 may include the nozzle 100 for supplying a treatment fluid onto the substrate W and a driving mechanism for moving the nozzle 100. For example, the treatment fluid may include de-ionized water (DIW), chemical, etc.

In particular, the driving mechanism may include a nozzle arm 32, a turning shaft 34 and a driving portion 36. The nozzle 100 may be attached to a front end of the nozzle arm 32 which is arranged substantially horizontally above the substrate W held by the spin head 22. A base end of the nozzle arm 32 may be fixed on the turning shaft 34 which is arranged in a substantially vertical direction, and a lower end of the turning shaft 34 may be connected to the driving portion 36.

The nozzle 100 may be moved between a process location and a standby location by the driving portion 36. The standby location is a location that is relatively more distant from the center of the spin head 22 than the process location. When the substrate W is loaded on or unloaded from the support unit 20, the holding members 24 are located at the standby location, and when a process is performed on the substrate W, the holding members 24 are located at the process location. The holding members are in contact with the side of the substrate W at the process location. By driving the driving portion 36, the nozzle arm 32 may be turned within a substantially horizontal plane about the turning shaft 34 so as to move the nozzle 100 integrally with the nozzle arm 32 from above a center portion of the wafer W to above the periphery of the wafer W. Additionally, the driving portion 36 may drive the turning shaft 34 to be raised and lowered so as to allow the nozzle 100 to be raised and lowered integrally with the nozzle arm 32 and the turning shaft 34.

The cup 40 may surround the wafer W which is supported on the spin head 22. The cup 40 may provide the space for performing a substrate processing process and an upper portion of the cup 40 may be opened.

For example, the cup 40 may include a first recovery vessel 42, a second recovery vessel 44 and a third recovery vessel 46. Each of the recovery vessels 42, 44 and 46 may recover different treatment fluids used in the cleaning process. The first recovery vessel 42 may have an annular ring shape surrounding the support unit 20, the second recovery vessel 44 may have an annular ring shape surrounding the first recovery vessel 42, and the third recovery vessel 46 may have an annular ring shape surrounding the second recovery vessel 44.

A first inner space 42a of the first recovery vessel 42, a second inner space 44a between the first recovery vessel 42 and the second recovery vessel 44, and a third inner space 46a between the second recovery vessel 44 and the third recovery vessel 46 may function as inlets through which the treatment fluids are introduced into the first recovery vessel 42, the second recovery vessel 44, and the third recovery vessel 46. The first to third recovery vessels 42, 44 and 46 may be connected to first to third recovery lines 43, 45 and 47. The first to third recovery vessels 42, 44 and 46 may discharge the treatment fluids introduced through the first to third recovery vessels 43, 45 and 47, respectively.

The elevation unit 50 may move the cup 40 upwards and downwards. The elevation unit 50 may move a plurality of the recovery vessels 42, 44 and 46 of the cup 40 together or individually. As the cup 40 is moved upwards and downwards, a relative height of the cup 40 to the support unit 20 may be changed. For example, the elevation unit 50 may include a bracket 52, a movable shaft 54 and a driving portion 56. The bracket 52 may be fixedly installed on an outer wall of the cup 40, and the movable shaft 54 which is moved upwards and downwards by the driving portion 56 may be fixedly coupled to the bracket 52.

When the substrate W is loaded or unloaded into or from the support unit 20, the cup 40 may be lowered by the elevation unit 50 such that the support unit 20 protrudes above the cup 40. When the process is performed, the height of the cup 40 may be adjusted such that the treatment fluid is introduced into the preset recovery vessel according to the kind of the treatment fluid supplied to the substrate W.

Hereinafter, the two-fluid nozzle in accordance with example embodiments will be explained with reference to FIGS. 2 to 8.

As illustrated in FIGS. 2 to 7, the nozzle 100 may include a gas supply passage 122 for supplying a gas such as nitrogen (N₂) to the inside thereof, a liquid supply passage 124 for supplying a liquid such as deionized water (DIW) to the inside thereof, a mixing chamber 114 for mixing the gas and the liquid to form liquid droplets and a discharge guide 116 for injecting the liquid droplets to the outside (e.g., outside of the nozzle 100). Additionally, the nozzle 100 may further include a distribution guide 129 (see FIG. 4), having a blocking plate 130 and a guide recess (e.g., groove) 132, disposed within the liquid supply passage 124 to guide distribution of a flow of the liquid.

The gas supply passage 122 may extend in a first direction. The gas supply passage 122 may have a cross-sectional shape of a circular or oval shape. A cross-sectional area of the gas supply passage 122 may be constant from an entrance to an exit. For example, the gas supply passage 122 may have a circular cross-sectional shape with a first diameter D1 of a constant size along a lengthwise direction.

The liquid supply passage 124 may be formed to surround the gas supply passage 122 along the lengthwise direction of the gas supply passage 122. The gas supply passage 122 may be arranged to pass through the liquid supply passage 124. The liquid supply passage 124 may have a cross-sectional shape of an annular shape. The liquid supply passage 124 may have a cylindrical shape with an annular cross-sectional shape. The liquid supply passage 124 may be connected to a liquid introduction passage 111 such that deionized water (DIW) may be introduced from the outside to the inside thereof. The liquid introduction passage 111 may open on an outer peripheral face of the liquid supply passage 124. The liquid introduction passage 111 may be connected to the liquid supply passage 124 to have a predetermined angle with respect to the annular shaped liquid passage of the liquid supply passage 124. For example, the liquid introduction passage 111 may be connected to the liquid supply passage to have a substantially right angle with respect to the outer peripheral face of the liquid supply passage 124 which extends in a direction parallel to the lengthwise of the gas supply passage 122.

The liquid supply passage 124 may include a tapered portion 125 which is formed with an inner diameter and an outer diameter which get smaller toward the exit of the gas supply passage 122. A cross-sectional area of the tapered portion 125 having an annular cross-sectional shape may be decreased gradually along the lengthwise of the gas supply passage 122. An exit of the tapered portion 125, that is, an exit of the liquid supply passage 124 may open toward a central axis of the exit of the gas supply passage 122. The exit of the liquid supply passage 124 may open in an annular shape between the exit of the gas supply passage 122 and an inlet of the mixing chamber 114. The tapered portion 125 is provided to be inclined downwards in a direction that faces a central axis X of the gas supply passage 122. For example, the tapered portion 125 may be inclined at an angle of about 40° to 80° with respect to the central axis X of the gas supply passage 122.

The mixing chamber 114 may be arranged to be spaced apart from the exit of the gas supply passage 122. The mixing chamber 114 may open to the gas supply passage 122 and the liquid supply passage 124. The mixing chamber 114 may extend in the first direction. The mixing chamber 114 may be arranged coaxially with the axis X of the gas supply passage 122. The mixing chamber 114 may have a cross-sectional shape of a circular shape or an oval shape. A cross-sectional area of the mixing chamber 114 may be constant from an entrance to an exit. For example, the mixing chamber 114 may have a circular cross-sectional shape with the second diameter D2 of a constant size along a lengthwise direction. Accordingly, the deionized water (DIW) supplied from the liquid supply passage 124 may be mixed with the nitrogen gas supplied from the gas supply passage 122 within the mixing chamber 114 to form liquid droplets.

The discharge guide 116 may be in fluid communication with the mixing chamber 114. The discharge guide 116 may extend in the first direction. The discharge guide 116 may be arranged coaxially with the axis X of the gas supply passage 122. The discharge guide 116 may have a cross-sectional shape of a circular shape or an oval shape. A cross-sectional area of the discharge guide 116 may be constant from an entrance to an exit. For example, the discharge guide 116 may have a circular cross-sectional shape with a third diameter D3 of a constant size along a lengthwise direction. Accordingly, the liquid droplets formed within the mixing chamber may move along an inner wall of the discharge guide 116 to be injected to the outside (e.g., outside of the nozzle 100).

In example embodiments, the first diameter D1 of the gas supply passage 122 may be substantially equal to the second diameter D2 of the mixing chamber 114. In example embodiments, the third diameter D3 of the discharge guide 116 may be smaller than the first diameter D1 of the gas supply passage 122. In addition, in example embodiments, the third diameter D3 of the discharge guide 116 may be smaller than the second diameter D2 of the mixing chamber 114. The gas supply passage 122 may have a first cross-sectional area, the mixing chamber 114 may have a second cross-sectional area the same as the first cross-sectional area, and the discharge guide 116 may have a third cross-sectional area smaller than the first cross-sectional area of the gas supply passage 122. In some example embodiments, the third cross-sectional area of the discharge guide 116 may be smaller than the second cross-sectional area of the mixing chamber 114. For example, a diameter ratio (D3/D2) of the discharge guide 116 and the mixing chamber 114 may range from 0.65 to 0.75. A discharge area (cross-section area of the exit) of the liquid supply passage 124 may range from 4 mm² to 10 mm².

The mixing chamber 114 may have a first length L1, and the discharge guide 116 may have a second length L2 greater than the first length L1. For example, a length ratio (L2/L2) of the discharge guide 116 and the mixing chamber 114 may range from 6 to 8. For example, the mixing chamber 114 may have the first length L1 of 4 mm to 10 mm, and the discharge guide 116 may have the second length L2 of 4 mm to 20 mm.

As illustrated in FIG. 3, the nozzle 100 may include a nozzle body 110 having a hollow portion 112 (e.g., as illustrated in FIG. 2), the mixing chamber 114 and the discharge guide 116 sequentially connected to the hollow portion 112, and an engagement member 120 (e.g., as illustrated in FIG. 2) engaged with the nozzle body 110 and having the gas supply passage 122 formed through the engagement member 120.

The hollow portion 112, the mixing chamber 114 and the discharge guide 116 may be formed coaxially with the central axis X and may extend in the first direction. A tapered face 113 may be formed to get narrower from the hollow portion 112 to the mixing chamber 114.

The engagement member 120 may include an insertion body 121 inserted into the hollow portion 112 and a head portion 123 arranged on a base end of the nozzle body 110. The insertion body 121 may include a first cylindrical portion 121a having a first outer diameter substantially the same as the inner diameter of the hollow portion 112, a second cylindrical portion 121b having a second diameter smaller than the first outer diameter, and a truncated conic portion 121c having a third diameter which gets narrower from the second cylindrical portion 121b to the mixing chamber 114.

The gas supply passage 122 may be formed to pass through the engagement member 120, and the exit of the gas supply passage 122 may be formed to open on a plane of a distal end of the truncated conic portion 121c.

The engagement member 120 may be spaced apart from an inner face of the hollow portion to form the liquid supply passage 124 for supplying the liquid. When the insertion body 121 is inserted and fixed into the hollow portion 112, as illustrated in FIG. 5, an annular gap, that is, the liquid supply passage 124 may be formed with an outer face of the second cylindrical portion 121b and the inner face of the hollow portion 112. Additionally, as illustrated in FIG. 7, an annular gap, for example, the tapered portion 125 may be formed between an outer face of the truncated conic portion 121c and the tapered face 113.

The head portion 123 may block an open end of the hollow portion 112, and a sealing member 140 such as an O-ring may be disposed between the nozzle body 110 and the engagement member 120 for airtightly sealing the hollow portion 112.

As illustrated in FIG. 4, in example embodiments, the distribution guide 129 may include a plurality of blocking plates 130 and a plurality of guide recesses 132 each formed between a pair of blocking plates 130. The plurality of blocking plates 130 are arranged to be spaced apart from each other along a circumferential direction within the liquid supply passage 124 so as to distribute a flow of the liquid. The guide recess 132 formed between the blocking plates 130 allows the liquid to pass therethrough.

The plurality of blocking plates 130 may form a blocking ring that includes blocking protrusions separated by the guide recesses 132 circumferentially surrounding the gas supply passage 122. Each of the blocking protrusions of the blocking ring may protrude from an outer face of the engagement member 120. For example, each of the blocking protrusions of the blocking ring may protrude from an outer surface of the second cylindrical portion 121b. The blocking plates 130 may extend parallel with the extending direction of the gas supply passage 122. Each blocking plates 130 may have a shape of a flange.

As illustrated in FIG. 6, a plurality of the blocking plates 130 may be spaced apart from each other along the circumferential direction within the liquid supply passage 124. Thus, the liquid flowing through the liquid supply passage 124 may pass through the guide recess 132 between the blocking plates 130, to thereby improve flow uniformity of the liquid through the liquid supply passage 124. Further, the uniformly distributed liquid may be discharged toward the central axis X of the exit of the gas supply passage 122 and may be mixed with the gas within the mixing chamber 114 to form the liquid droplets.

As illustrated in FIG. 8, the substrate processing apparatus 10 may further include a gas supply unit configured to supply the gas to the gas supply passage 122 of the nozzle 100 and a liquid supply unit configured to supply the liquid to the liquid supply passage 124 of the nozzle 100.

In particular, the gas supply unit may include a gas supply pipe 62, a first flow meter 64, and a first flow rate adjusting valve 66. The gas supply pipe 62 may be connected to the gas supply passage 122 to supply the gas from a gas supply source 60. The gas supply source 60 may supply a nitrogen (N₂) gas. The first flow meter 64 may be installed in the gas supply pipe 62 to detect a flow rate of the gas flowing through the gas supply pipe 62. The first flow rate adjusting valve 66 may control the flow rate of the gas flowing through the gas supply pipe 62 based on the detected gas flow rate. A controller 80 may output a first control signal to the first flow rate adjusting valve 66 in response to the flow rate detection valve from the first flow meter 64, to control an opening degree of the first flow rate adjusting valve 66.

The liquid supply unit may include a liquid supply pipe 72, a second flow meter 74, and a second flow rate adjusting valve 76. The liquid supply pipe 72 may be connected to the liquid introduction passage 111 to supply the liquid from a liquid supply source 70. The liquid supply source 70 may supply deionized water (DIW) or chemical. The second flow meter 74 may be installed in the liquid supply pipe 72 to detect a flow rate of the liquid flowing through the liquid supply pipe 72. The second flow rate adjusting valve 76 may control the flow rate of the liquid flowing through the liquid supply pipe 72 based on the detected liquid flow rate. The controller 80 may output a second control signal to the second flow rate adjusting valve 76 in response to the flow rate detection valve from the second flow meter 74, to control an opening degree of the second flow rate adjusting valve 76.

Additionally, the controller 80 may control a flow rate ratio of the gas and the liquid. For example, the controller 80 may control to supply the liquid of a constant flow rate even though the gas flow rate is changed.

In example embodiments, the nozzle body 110 may include conductive resin. The nozzle body 110 and the engagement member 120 may include conductive synthetic resin. The nozzle 100 including a conductive resin material may be grounded. Thus, an electrostatic charge may be prevented from occurring when the liquid droplets are injected onto the substrate W.

The nozzle body 110 and the engagement member 120 may include non-conductive resin and carbon (C) based, silicon (Si) based or metal based filler. The silicon based filler may include silicon, silicon carbide, etc. The metal based filler include titanium, tantalum, zirconium or a combination thereof. For example, the nozzle 100 may have a resistance of about 100 kΩ or less.

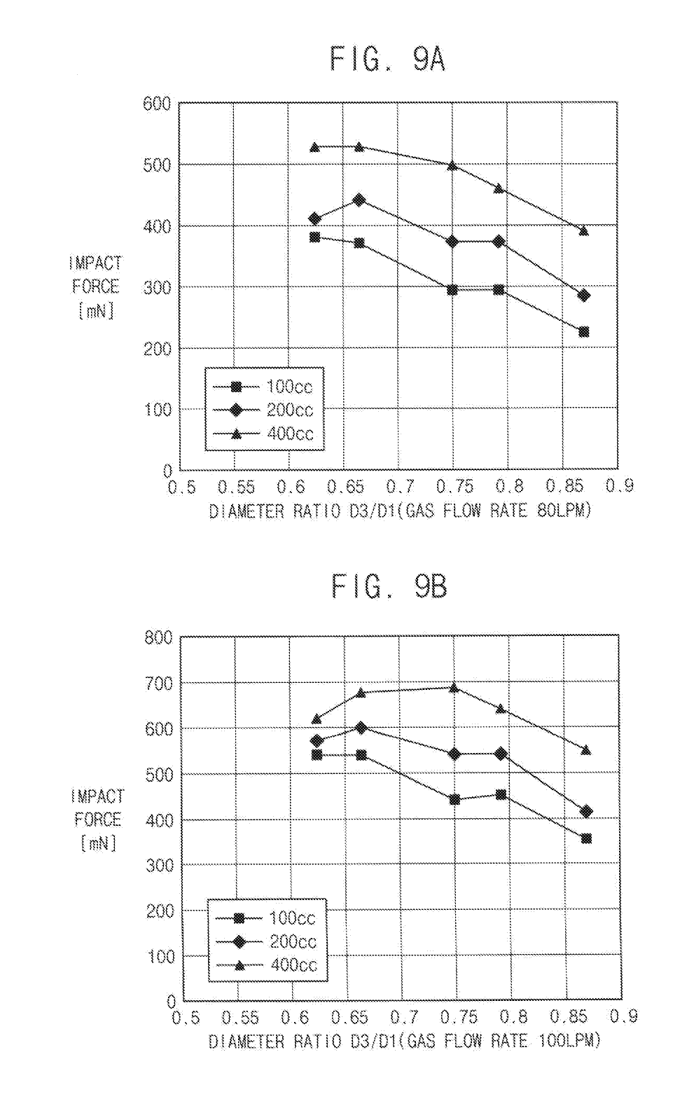

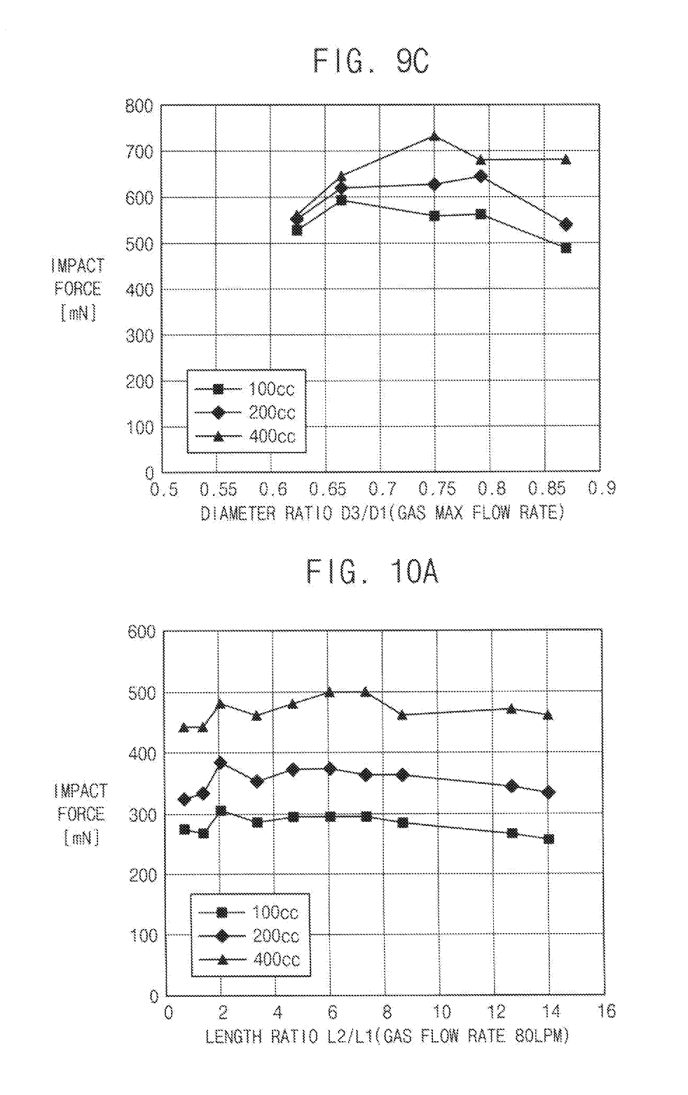

FIGS. 9A to 9C are graphs illustrating an impact force (liquid-driving power) of injected liquid droplets according to a diameter ratio of a discharge guide and a gas supply passage (mixing chamber).

Referring to FIGS. 9A to 9C, as the gas flow rate is increased (80 LPM, 100 LPM, gas max. flow rate), the impact force may be increased overall. For example, when the diameter ratio (D3/D1, or D3/D2) of the discharge guide 116 and the gas supply passage 122 is from 0.65 to 0.75, the increased width of the impact force with the increase in the gas flow rate may be the largest. Further, when the diameter ratio (D3/D1) of the discharge guide 116 and the gas supply passage 122 is from 0.65 to 0.75, it may be suitable for a high flow rate nozzle (for example, liquid amount of 200 cc or more). Especially, when the diameter ratio (D3/D1) of the discharge guide 116 and the gas supply passage 122 is 0.75, it may be suitable for a high impact force nozzle (for example, max. gas amount of 110 LMP or more, liquid amount of 200 cc or more).

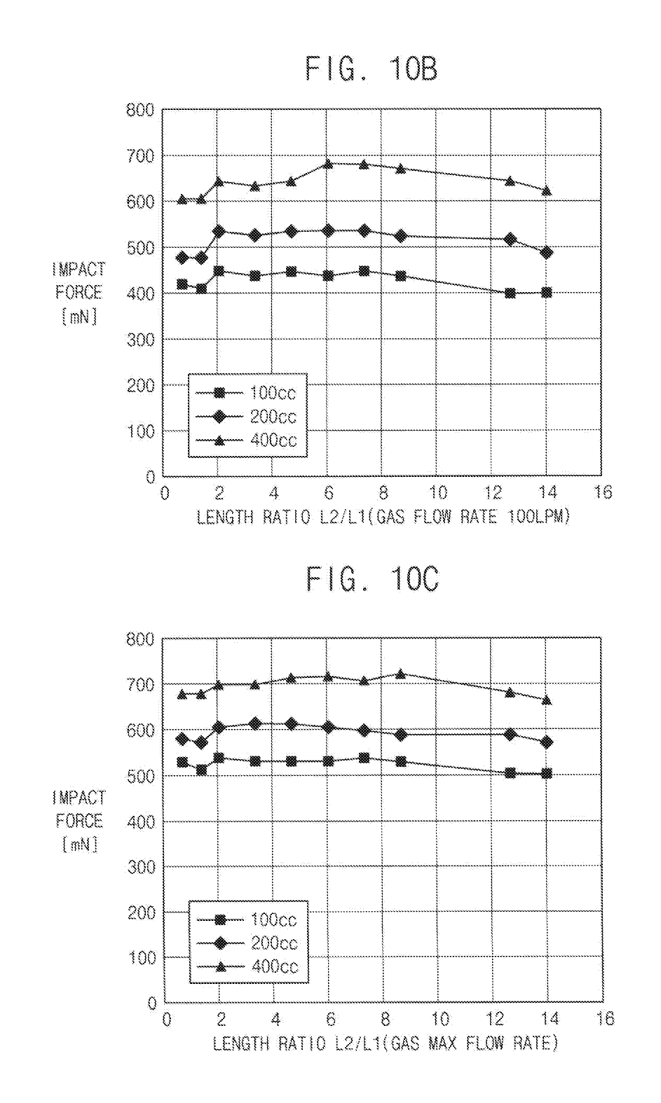

FIGS. 10A to 10C are graphs illustrating an impact force (liquid-driving power) of injected liquid droplets according to a length ratio of a discharge guide and a mixing chamber.

Referring to FIGS. 10A to 10C, as the gas flow rate is increased (80 LPM, 100 LPM, gas max. flow rate), the impact force may be increased overall. For example, when the length ratio (L2/L1) of the discharge guide 116 and the mixing chamber 114 is from 6 to 8, the increase width of the impact force with the increase in the gas flow rate may be the largest. Further, when the length ratio (L2/L1) of the discharge guide 116 and the mixing chamber 114 is from 6 to 8, it may be suitable for a high flow rate nozzle (for example, liquid amount of 200 cc or more). Especially, when the length ratio (L2/L1) of the discharge guide 116 and the mixing chamber 114 is 6, it may be suitable for a high flow rate nozzle (for example, max. gas amount of 110 LMP or more, liquid amount of 200 cc or more).

As mentioned above, the diameter D1 of the gas supply passage 122 may be substantially the same as the diameter D2 of the mixing chamber 114, and the diameter D3 of the discharge guide 116 may be smaller than the diameter D1 of the gas supply passage 122. The length L2 of the discharge guide 116 may be greater than the length L2 of the mixing chamber 114.

Embodiments may be illustrated herein with idealized views (although relative sizes may be exaggerated for clarity). It will be appreciated that actual implementation may vary from these exemplary views depending on manufacturing technologies and/or tolerances. Therefore, descriptions of certain features using terms such as “same,” “equal,” and geometric descriptions such as “planar,” “coplanar,” “cylindrical,” “square,” etc., as used herein when referring to orientation, layout, location, shapes, sizes, amounts, or other measures, encompass acceptable variations from exact identicality, including nearly identical layout, location, shapes, sizes, amounts, or other measures within acceptable variations that may occur, for example, due to manufacturing processes. The term “substantially” may be used herein to emphasize this meaning, unless the context or other statements indicate otherwise.

Additionally, the diameter ratio (D3/D1) of the discharge guide 116 and the gas supply passage 122 may be from 0.65 to 0.75, and the length ratio (L2/L1) of the discharge guide 116 and the mixing chamber 114 is from 6 to 8. The nozzle having the predetermined ranges may generate liquid droplets having relatively high impact force to remove contaminants on the substrate and improve cleaning efficiency. Accordingly, the nozzle may be used as a high flow rate nozzle or a high impact force nozzle.

Further, the blocking plates 130 may be formed within the liquid supply passage 124 to improve flow uniformity of the supplied liquid, and the nozzle 100 may include a conductive synthetic resin and may be grounded to remove an electrostatic charge in the liquid droplet.

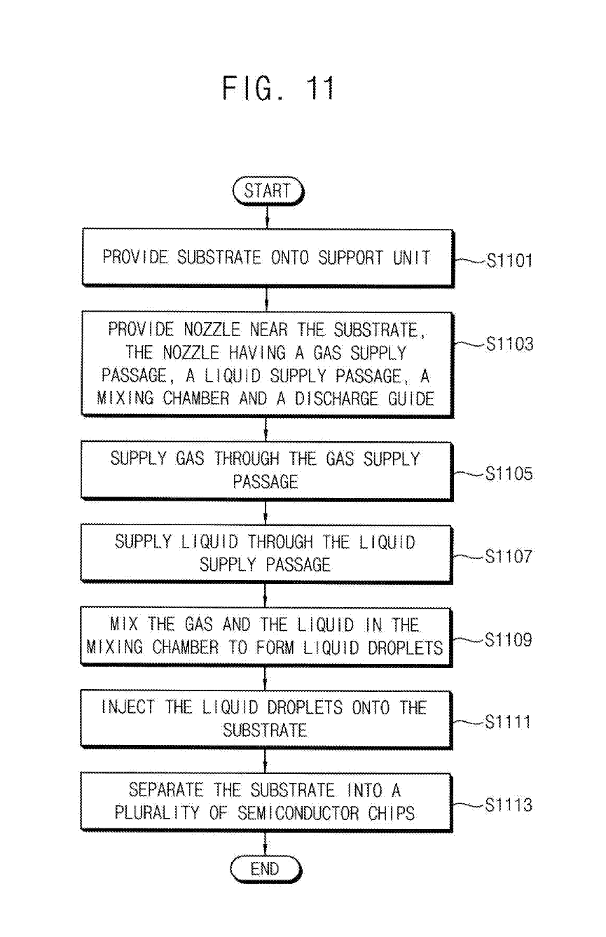

FIG. 11 is flow chart showing a method of processing a substrate according to exemplary embodiments of the present disclosure.

In step S1101, a substrate is provided onto a support unit. The support unit may be a support unit 20 and the substrate may be a substrate W according to the exemplary embodiments as disclosed above. The support unit 20 may support and rotate the substrate W during processing (e.g., cleaning) of the substrate W.

In step S1103, a nozzle is provided near the substrate W. The nozzle may be a nozzle 100 according to the exemplary embodiments as disclosed above. The nozzle 100 may include a gas supply passage 122, a liquid supply passage 124, a mixing chamber 114 and a discharge guide 116.

In step S1105, a gas (e.g., nitrogen) is supplied through the gas supply passage 122. The gas supply passage 122 extends in a first direction to supply the gas therethrough.

In step S1107, a liquid (e.g., deionized water or chemical) is supplied through the liquid supply passage 124. The liquid supply passage 124 surrounds the gas supply passage 122 along a lengthwise direction of the gas supply passage 122 to supply the liquid toward a central axis of an exit of the gas supply passage 122.

In step S1109, the gas and the liquid is mixed in the mixing chamber 114 to form liquid droplets. The mixing chamber 114 extends in the first direction, spaced apart from the exit of the gas supply passage 122 and opening to the gas supply passage 122 and the liquid supply passage 124 to mix the gas and the liquid to form the liquid droplets.

In step S1111, the liquid droplets are injected outside of the nozzle 100 onto the substrate W to clean the substrate W.

In step S1113, after cleaning the substrate W in step S1111, the substrate W may be separated into a plurality of semiconductor chips, which form semiconductor devices that may be included in packages or modules.

In some embodiments, the gas supply passage 122 has a first cross-sectional area, the mixing chamber 114 has a second cross-sectional area substantially the same as the first cross-sectional area, and the discharge guide 116 has a third cross-sectional area smaller than the first cross-sectional area.

The above-mentioned substrate processing apparatus may be used to manufacture a semiconductor device such as a logic device or a memory device. For example, the semiconductor device may include logic devices such as central processing units (CPUs), main processing units (MPUs), or application processors (APs), or the like, and volatile memory devices such as DRAM devices, SRAM devices, or non-volatile memory devices such as flash memory devices, PRAM devices, MRAM devices, ReRAM devices, or the like.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is claimed is:

1. A nozzle, comprising:
a gas supply passage extending in a first direction along an axis to supply a gas therethrough;
a liquid supply passage surrounding the gas supply passage along a lengthwise direction of the gas supply passage to supply a liquid toward a central axis of an exit of the gas supply passage;
a mixing chamber extending in the first direction, spaced apart from the exit of the gas supply passage and opening to the gas supply passage and the liquid supply passage to mix the gas and the liquid to form liquid droplets; and
a discharge guide arranged coaxially with the axis of the gas supply passage and in fluid communication with the mixing chamber to inject the liquid droplets to the outside of the nozzle,
wherein the gas supply passage has a first cross-sectional area, the mixing chamber has a second cross-sectional area substantially the same as the first cross-sectional area, and the discharge guide has a third cross-sectional area smaller than the first cross-sectional area.

2. The nozzle of claim 1, wherein the liquid supply passage has an annular cross-sectional area surrounding the gas supply passage.

3. The nozzle of claim 1, further comprising a distribution guide including a plurality of blocking plates which are arranged to be spaced apart from each other along a circumferential direction within the liquid supply passage.

4. The nozzle of claim 3, wherein a guide recess is formed between the blocking plates to allow the liquid to pass therethrough.

5. The nozzle of claim 3, wherein the liquid supply passage includes a tapered portion arranged under the distribution guide and having an inner diameter and an outer diameter which get smaller toward the exit of the gas supply passage.

6. The nozzle of claim 1, wherein a diameter ratio (D3/D2) of the discharge guide to the mixing chamber is a ratio in a range between 0.65 to 0.75.

7. The nozzle of claim 1, wherein a length ratio (L2/L1) of the discharge guide to the mixing chamber is a ratio in a range between 6 to 8.

8. The nozzle of claim 1, further comprising a liquid introduction passage connected to the liquid supply passage to introduce the liquid to the inside thereof.

9. The nozzle of claim 1, wherein the nozzle comprises a nozzle body having a hollow portion, the mixing chamber and the discharge guide sequentially connected to the hollow portion, and an engagement member having the gas supply passage formed therethrough, inserted and fixed into the hollow portion and spaced apart from an inner face of the hollow portion to form the liquid supply passage.

10. The nozzle of claim 9, wherein the nozzle body comprises conductive resin.

11. A nozzle, comprising:
a nozzle body having a hollow portion, and a mixing chamber and a discharge guide sequentially connected to the hollow portion; and
an engagement member having a gas supply passage formed to supply a gas therethrough, inserted and fixed into the hollow portion and spaced apart from an inner face of the hollow portion to form a liquid supply passage which supplies a liquid toward a central axis of an exit of the gas supply passage;
wherein the mixing chamber is connected to the gas supply passage and the liquid supply passage to form liquid droplets, and
wherein the gas supply passage has a first cross-sectional area, the mixing chamber has a second cross-sectional area substantially the same as the first cross-sectional area, and the discharge guide has a third cross-sectional area smaller than the first cross-sectional area.

12. The nozzle of claim 11, further comprising a distribution guide including a plurality of flanges which are arranged to be spaced apart from each other along a circumferential direction within the liquid supply passage.

13. The nozzle of claim 11, wherein a diameter ratio (D3/D2) of the discharge guide to the mixing chamber is a ratio in a range between 0.65 to 0.75.

14. The nozzle of claim 11, wherein a length ratio (L2/L1) of the discharge guide to the mixing chamber is a ratio in a range between 6 to 8.

15. The nozzle of claim 11, wherein the nozzle body comprises conductive resin.

16. A substrate processing apparatus, comprising;
a support unit configured to support a substrate; and
an injection unit having a nozzle configured to mix a gas and a liquid to form liquid droplets therein and inject the liquid droplets onto the substrate,
the nozzle comprising:
a gas supply passage extending in a first direction to supply the gas therethrough;
a liquid supply passage surrounding the gas supply passage along a lengthwise direction of the gas supply passage to supply the liquid toward a central axis of an exit of the gas supply passage;
a mixing chamber extending in the first direction, spaced apart from the exit of the gas supply passage and opening to the gas supply passage and the liquid supply passage to mix the gas and the liquid to form the liquid droplets; and
a discharge guide arranged coaxially with an axis of the gas supply passage and in fluid communication with the mixing chamber to inject the liquid droplets to the outside of the nozzle,
wherein the gas supply passage has a first cross-sectional area, the mixing chamber has a second cross-sectional area substantially the same as the first cross-sectional area, and the discharge guide has a third cross-sectional area smaller than the first cross-sectional area.

17. The substrate processing apparatus of claim 16, further comprising a distribution guide including a plurality of blocking plates which are arranged to be spaced apart from each other along a circumferential direction within the liquid supply passage.

18. The substrate processing apparatus of claim 16, wherein a diameter ratio (D3/D2) of the discharge guide to the mixing chamber is a ratio in a range between 0.65 to 0.75.

19. The substrate processing apparatus of claim 16, wherein the nozzle includes a nozzle body comprising conductive resin and the nozzle is grounded.

20. The substrate processing apparatus of claim 16, further comprising
a gas supply unit including a gas supply pipe connected to the gas supply passage to supply the gas from a gas supply source, a first flow meter installed in the gas supply pipe to detect a flow rate of the gas flowing through the gas supply pipe, and a first flow rate adjusting valve configured to control the flow rate of the gas flowing through the gas supply pipe based on the detected gas flow rate; and
a liquid supply unit including a liquid supply pipe configured to supply the liquid from a liquid supply source to the liquid supply passage, a second flow meter installed in the liquid supply pipe to detect a flow rate of the liquid flowing through the liquid supply pipe, and a second flow rate adjusting valve configured to control the flow rate of the liquid flowing through the liquid supply pipe based on the detected liquid flow rate.
